(19) United States
(12) Patent Application Publication
(10) Pub. No.: US 2008/0121952 A1
(43) Pub. Date: May 29, 2008

(54) CMOS IMAGE SENSOR

(76) Inventor: Kyong-Tae Chu, Gyeonggi-do (KR)

Correspondence Address: SHERR & NOURSE, PLLC, 620 HERNDON PARKWAY, SUITE 200, HERNDON, VA, 20170, US

(21) Appl. No.: 11/923,389

(22) Filed: Oct. 24, 2007

(30) Foreign Application Priority Data
Nov. 27, 2006 (KR) 10-2006-0117378

(51) Int. Cl. H01L 27/146; H01L 31/18

(52) U.S. Cl. 257/292; 438/59; 257/E27.133

(57) ABSTRACT

Embodiments relate to a CMOS image sensor and a method of fabricating the same. In embodiments, a recessed gate of a transfer transistor (Tx) may be formed. In embodiments, a device isolation layer may be formed on a semiconductor substrate including an epitaxial layer, a recessed gate electrode pattern of a transfer transistor may be formed to penetrate an inside of the substrate including the epitaxial layer, a photodiode area may be formed on the epitaxial layer next to one side of the recessed gate electrode pattern, a trap preventing layer may be formed on the photodiode area, and a drain region may be formed within a surface of the substrate next to the other side of the recessed gate electrode pattern.

The present application claims priority under 35 U.S.C. 119 and 35 U.S.C. 365 to Korean Patent Application No. 10-2006-0117378 (filed on Nov. 27, 2006), which is hereby incorporated by reference in its entirety.

### BACKGROUND

A CMOS image sensor may be a device that uses a switching system and may include as many MOS transistors as a number of pixels. A CMOS device may include, as peripheral circuits, a control circuit and a signal processing circuit, and may sequentially detect outputs using such circuits. A CMOS image sensor may include a photodiode and a MOS transistor in a unit pixel, and may sequentially detect electrical signals in a switching manner to realize an image. According to CMOS technology, a control circuit and a signal processing circuit may be used as a peripheral circuit, and may sequentially detect outputs using the MOS transistors.

A CMOS image sensor may be driven and may be capable of implementing various scanning systems. In a CMOS image sensor, a signal processing circuit may be integrated on a single chip, which may enable a product to be downsized with a reduced product cost. This may be because of the compatibility of the CMOS technology. Moreover, since power consumption of the CMOS image sensor may be considerably smaller than that of a CCD, the CMOS image sensor may be widely used in various products.

FIG. 1 is a circuit diagram of a unit pixel of a 4-T CMOS image sensor.

Referring to FIG. 1, a unit pixel of a 4-T CMOS image sensor may include a photodiode (PD) as a photosensor and four NMOS transistors Tx, Rx, Dx, and Sx.

Transfer transistor Tx among the four NMOS transistors may play a role in delivering photogenerated charges from the photodiode (PD) to a floating sensing node.

The reset transistor Rx may function to discharge charges stored in the floating sensing node for signal detection.

Drive transistor Dx may be a source follower and select transistor Sx may be provided for switching and addressing.

A DC gate may be a load transistor that may enable a constant current to flow by applying a constant voltage as a gate potential of transistor. ‘VDD’ indicates a drive power source voltage and ‘VSS’ indicates a ground voltage.

A related art CMOS image sensor will be described with reference to the drawings.

FIG. 2A and FIG. 2B are cross-sectional diagrams of a photodiode and a gate of a transfer transistor in a CMOS image sensor according to a related art.

Referring to FIG. 2A, p− type epitaxial layer 201 may be formed on a p++ type semiconductor substrate 200. Device isolation layer 203 may be provided to a device isolation area of semiconductor substrate 200, which may be divided into an active area and the device isolation area.

Gate 213, which may include gate insulating layer 211 underneath, may be formed on the epitaxial layer 201 for a transfer transistor. p-layer type channel region 215 for adjusting a gate voltage Vt may be provided below gate 213. Channel region 215 may facilitate electrons in n− type photodiode area 221 to go to transfer transistor Tx in a manner of lowering a gate voltage of transfer transistor Tx by reducing a doping concentration. Yet, in a related art CIS circuit design, select transistor Sx and transfer transistor Tx may be designed to have the same gate voltage. This may make it difficult to change implantation conditions for the gate voltage of transfer transistor Tx.

Subsequently, n− type photodiode area 221 and p+ type trap preventing layer 223 may be formed in photodiode area epitaxial layer 201.

p+ type trap preventing layer 223 may be formed on n− type photodiode area 221. p+ type trap preventing layer 223 may be an ion-implanted area which may prevent a space charge area of n− type photodiode area 221 from contacting with a silicon surface. Drain region 231 may be formed as an n+ diffusion region.

FIG. 2B is an enlarged diagram of view ‘X’ illustrated in FIG. 2A.

Zone-A is a portion of n− type photodiode area 221 adjacent to transfer transistor Tx. Zone-B is an internal area of n− type photodiode area 221. Concentration adjustment of the n− type photodiode area 221 may have the following tradeoff relation.

Zone-A may need to have a high doping concentration to enable electrons gathering in the n− type photodiode area 221 to appropriately go to channel region 215 of transfer transistor Tx. If the doping concentration of zone-A is low, a space charge area may be broadened to raise an energy barrier. Hence, even if the gate of transfer transistor Tx is turned on, the electrons gathering in n− type photodiode area 221 may fail to completely go to transfer transistor Tx.

On the other hand, zone-B of n− type photodiode area 221 should preferably stay completely in depletion until light comes therein. Hence, the doping concentration should be low.

Namely, if the doping concentration of n− type photodiode area 221 is set low and if a thickness of p+ type trap preventing layer 223 is reduced to be thin, n− type photodiode area 221 may get closer to the silicon surface and may reduce the length of zone-C. This may enable the energy barrier not to be excessively raised. Yet, if n− type photodiode area 221 gets closer to the silicon surface, current by unwanted electrons generated from the silicon surface may affect CIS pixels negatively. Hence, in zone-A, p+type trap preventing layer 223 should have both high concentration and appropriate thickness.

The related art structure may have a problem in that zone-A of n− type photodiode area 221 may need to have high a electron concentration, while zone-B may need to have a low electron concentration. However, a limitation may be put on a setting process conditions suitable for solving the problem.

### SUMMARY

Embodiments relate to a CMOS image sensor and a method of fabricating a CMOS sensor.

Embodiments may be suitable for a wide scope of applications, and may be suitable for forming a recessed gate of a transfer transistor (Tx).

Embodiments may relate to a CMOS image sensor and fabricating method thereof which may enhance operational characteristics of a device by providing a recessed gate to a transfer transistor Tx.

Embodiments may relate to a CMOS image sensor, which may have a recessed gate configured by a recessed gate electrode pattern of a transfer transistor which may penetrate an inside of a substrate instead of a semiconductor substrate surface.

According to embodiments, a method of fabricating a CMOS image sensor may include forming a device isolation layer on a semiconductor substrate including an epitaxial layer, forming a recessed gate electrode pattern of a transfer transistor to penetrate an inside of the substrate including the epitaxial layer, forming a photodiode area on the epitaxial layer next to one side of the recessed gate electrode pattern, forming a trap preventing layer on the photodiode area, and forming a drain region within a surface of the substrate next to the other side of the recessed gate electrode pattern.

According to embodiments, the photodiode area may include a lightly doped n type diffusion area.

According to embodiments, the trap preventing layer formed on the photodiode area may include a heavily doped p type diffusion area.

According to embodiments, the drain region may include a heavily doped n type diffusion area.

According to embodiments, the semiconductor substrate may include a heavily doped p type (p++) substrate and the epitaxial layer may include a lightly doped p type (p−) epitaxial layer.

According to embodiments, forming a recessed gate electrode pattern may include forming a nitride layer on the substrate having a prescribed lower structure provided underneath and patterning the nitride layer, forming a trench to form a gate of the transfer transistor by performing dry etch on the substrate using the patterned nitride layer as an etch mask, forming a gate oxide layer on a whole surface of the substrate including the trench, and forming the recessed gate electrode pattern on the trench by forming and patterning polysilicon on the gate oxide layer.

According to embodiments, the trench may be etched to have a slope of 30˜90 degrees according to a design rule.

According to embodiments, the trench may be formed to have a depth 0.5˜2 times greater than that of the trap preventing layer.

According to embodiments, a CMOS image sensor may include a photodiode area, a lower structure including a trap preventing layer on the photodiode area and a drain region, and an electrode pattern of a recessed gate structure provided within the semiconductor substrate provided with the lower structure.

According to embodiments, the electrode pattern of the recessed gate structure may be configured to have a sloe of 30˜90 degrees and a depth 0.5˜2 times greater than that of the trap preventing layer.

### DRAWINGS

FIG. 1 is a circuit diagram of a unit pixel of a 4-T CMOS image sensor.

FIG. 2A is a cross-sectional diagram of a related art CMOS image sensor.

FIG. 2B is an enlarged cross-sectional diagram of view ‘X’ illustrated in FIG. 2A.

FIG. 3 is a cross-sectional diagram of a CMOS image sensor according to embodiments.

FIGS. 4A to 4E are cross-sectional diagrams of a gate of a transfer transistor in a CMOS image sensor according to embodiments.

FIG. 5 is an enlarged cross-sectional diagram of view ‘Y’ illustrated in FIG. 3.

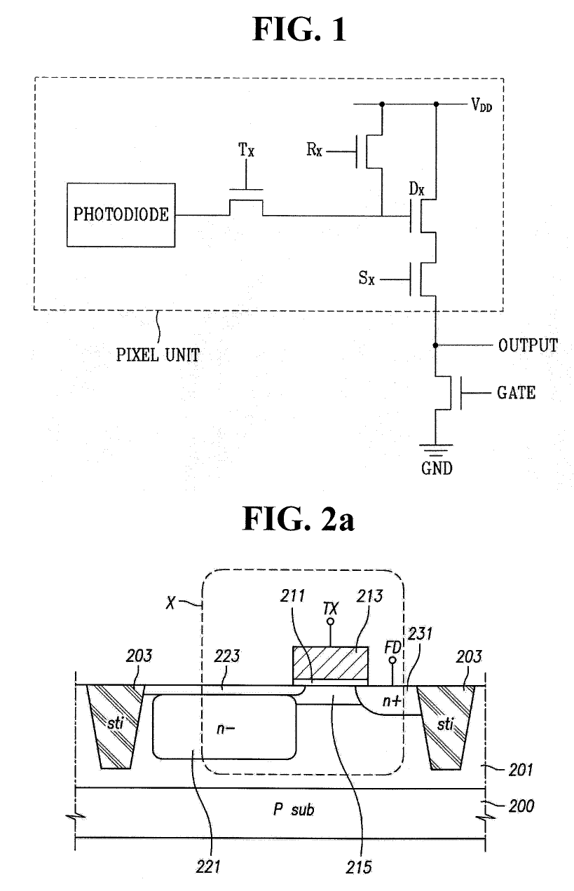

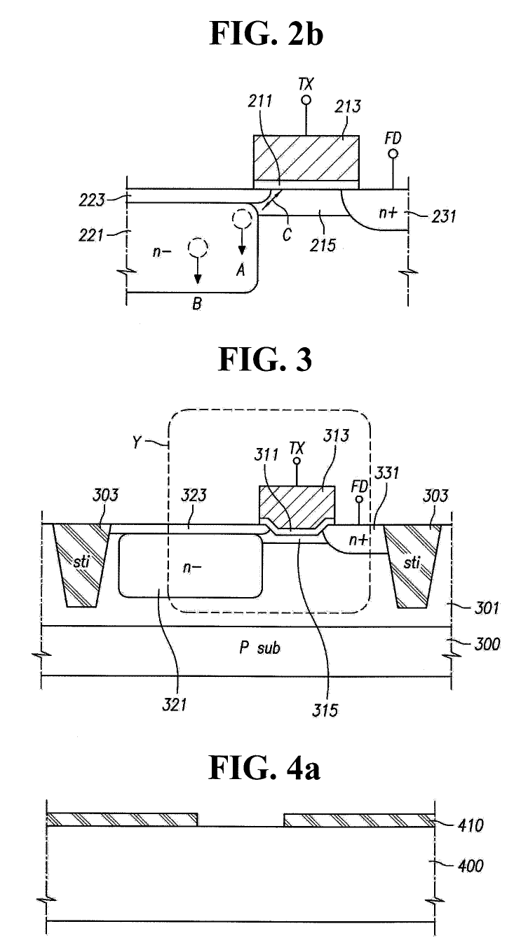

### DESCRIPTION

FIG. 3 is a cross-sectional diagram of a photodiode and a transfer transistor in a CMOS image sensor according to embodiments.

Referring to FIG. 3, p− type epitaxial layer 301 may be formed on first semiconductor substrate 300 of p++ type.

Device isolation layer 303 may be provided at a device isolation area of semiconductor substrate 300, and may divide an active area and the device isolation area. According to embodiments, the active area of semiconductor substrate 300 may be defined as a photodiode area and a transistor area.

First gate electrode pattern 313, which may be configured to be recessed and may have gate oxide layer 311 underneath, may be formed on a portion of epitaxial layer 301 for a transfer transistor. In embodiments, an insulating sidewall (not shown in the drawing) may be provided to both lateral sides of recessed first gate electrode pattern 313. Moreover, p-layer type channel 315 may be formed under recessed first gate electrode pattern 313, i.e., on a surface of the first semiconductor substrate, and may adjust a gate voltage Vt of the transfer transistor.

Photodiode area (PD) 321, which may include an n− type diffusion area, may be formed on epitaxial layer 301 at one side of recessed first gate electrode pattern 313. According to embodiments, trap preventing layer 323, which may include a heavily doped p type (P+), may be formed on photodiode area 321. According to embodiments, trap preventing layer 323 may be a heavily doped p type diffusion area corresponding to an ion-implanted portion, and may prevent a space charge area of n− type photodiode area 321 from contacting the silicon surface. Trap preventing layer 323 may assist in preventing a flow of unwanted current by the traps on the silicon surface instead of current by light.

Drain region 331 may be formed in a surface of semiconductor substrate 300 at the other side of recessed first gate electrode pattern 313. According to embodiments, drain region 331 may include a heavily doped n type (n+) diffusion area.

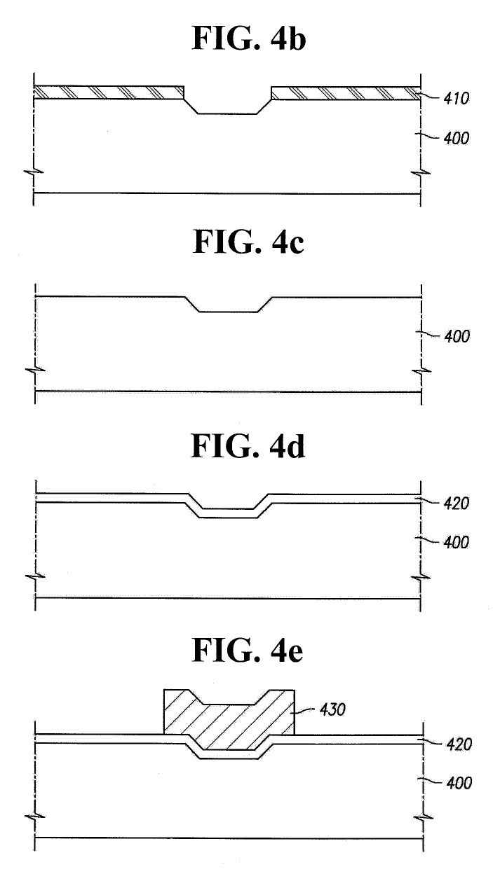

FIGS. 4A to 4E are cross-sectional diagrams illustrating a gate of a transfer transistor in a CMOS image sensor according to embodiments.

Referring to FIG. 4A, a nitride layer may be formed on second semiconductor substrate 400 and may be patterned to form a plurality of nitride layer patterns for a recessed gate structure. The nitride layer pattern may be used as etch mask 410.

Referring to FIG. 4B, a prescribed dry etch process may be carried out on second semiconductor substrate 400 using the nitride pattern as etch mask 410 to form a trench for the recessed gate structure.

In embodiments, a slope and depth of the trench may be controllable. In embodiments, the slope of the trench may be adjusted between 30˜90 degrees according to a device design rule. In embodiments, a depth of the trench may be adjusted within a range of 0.5˜2 times of a depth of the trap preventing layer (‘323’ in FIG. 3) including the heavily doped p type diffusion area according to the design rule.

Referring to FIG. 4C, etch mask 410 used to form the trench in second semiconductor substrate 400 may be removed. In embodiments, the nitride of etch mask 410 may be removed by wet etch, for example using H₃PO₄.

Referring to FIG. 4D, gate oxide layer 420 of SiO₂ may be formed on a surface, for example the entire surface, of second semiconductor substrate 400 including the trench.

Referring to FIG. 4E, polysilicon may be deposited on gate oxide layer 420 deposited on the entire substrate, and may form an electrode pattern in a recessed gate structure. The deposited polysilicon may then be etched to from recessed second gate electrode pattern 430.

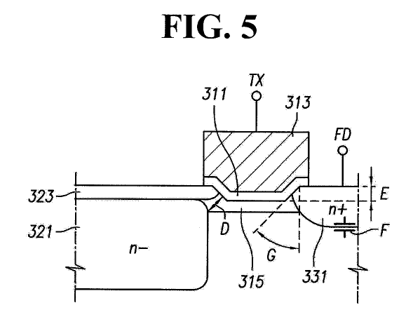

FIG. 5 is an cross-sectional diagram of view ‘Y’ illustrated in FIG. 3.

Referring to FIG. 5, a recessed gate electrode pattern of a transfer transistor may be configured to penetrate an inside of silicon instead of a surface of the silicon. The recessed gate structure may provide a distance between the n− type diffusion area of photodiode area 321 and channel 315 of transfer transistor Tx, i.e., zone-D may become smaller than that of the related art structure. In embodiments, even if a doping concentration of the n− type diffusion area is lowered, the energy barrier between the n− type diffusion area and channel 315 of transfer transistor Tx may not be considerably high. In embodiments, even if the electron concentration of the n− diffusion area is lowered, it may be able to lower the height of the energy barrier to some extent by optimizing zone-D to correspond to the instance between the n− type diffusion area and channel 315 of transfer transistor Tx. In embodiments, this optimization may be carried out by adjusting a depth of the recessed gate electrode pattern indicated by zone-E and a slope indicated by zone-G.

If the recessed gate structure is used, zone-D, which may be the distance between the n− type diffusion area of the photodiode and channel 315 of transfer transistor Tx, may become shorter. Yet, since it may be able to maintain the depth of trap preventing layer 323 including the p+ type diffusion area intact, a leakage current generated from the silicon surface may not negatively affect CIS pixel characteristics.

As the implantation condition of the gate voltage (Vt) may maintain the previous process condition as it is, the gate voltage of transfer transistor Tx may have the same gate voltage of select transistor Sx of CIS circuit.

In embodiments, if the recessed gate structure is used, the sensitivity of the CIS pixel may be considerably enhanced with the aforesaid effect. This may be because junction capacitance indicated by zone-G in the heavily doped n type (n+) drain region 331 called a floating diffusion area may be reduced. Electrons generated from photodiode area 321 may be transformed into voltage from charge by the junction capacitance of the floating diffusion area. In embodiments, this meaning is represented as Formula 1.

$$Δ V = \frac{Δ Q}{{C}_{FD}} \qquad [ Formula 1 ]$$

In Formula 1, CFD is junction capacitance by a floating diffusion area, ΔQ is variation of charge quantity by electrons migrating into the floating diffusion area from photodiode area 321, ΔV is voltage transformed from ΔQ by C_{FD}.

According to embodiments, as may be observed through Formula 1, if the junction capacitance of the floating diffusion area gets smaller, it may be able to induce a considerable voltage variation with a small charge quantity.

The recessed gate structure may thus contribute to the sensitivity improvement.

In embodiments, the photodiode area, including the n− type diffusion area, and the transfer transistor (Tx), including the electrode pattern of the recessed structure, may be used. If the n− type photodiode area is lightly doped, the n− type diffusion area may be easily and completely depleted before light comes in.

Since the distance between the n− type photodiode area and the channel of transfer transistor Tx may become shorter, electrons in the photodiode area may be facilitated to migrate into transfer transistor Tx.

A thickness adjustment of the trap preventing layer may assist in enabling the leakage current generated from the silicon surface to not affect the CIS pixel operation. The p type channel region under the gate electrode may enable the same gate voltage of select transistor Sx of the CIS pixel circuit, which may be difficult to be changed.

If the recessed gate structure is used, it may be unnecessary to change the thickness of the p+ layer type trap preventing layer injected into the silicon surface and the process condition of implantation of the P type channel region for adjusting the gate voltage.

Moreover, a sensitivity may be considerably enhanced because the junction capacitance of the floating diffusion area may be reduced.

Embodiments may use the photodiode having the n− type diffusion area and the transfer transistor having the electrode pattern of the recessed gate structure to provide various effects.

For example, if an n− type photodiode area is lightly doped, an n− type diffusion area may be facilitated to be completely depleted before light comes in.

In embodiments, since a distance between an n− type photodiode area and a channel of a transfer transistor Tx may get shorter, electrons in a photodiode area may be facilitated to migrate into transfer transistor Tx.

Moreover, a thickness adjustment of a trap preventing layer may assist in enabling leakage current generated from a silicon surface to not affect a CIS pixel operation. A p type channel region under a gate electrode may enable the same gate voltage of a select transistor Sx of a CIS pixel circuit, thereby being difficult to be changed. In embodiments, if a recessed gate structure is used, it may be unnecessary to change the thickness of a p+ layer type trap preventing layer injected into the silicon surface and a process condition of implantation of a P type channel region for adjusting the gate voltage.

Sensitivity may also be enhanced because junction capacitance of a floating diffusion area may be reduced.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A method, comprising:
forming a device isolation layer over a semiconductor substrate including an epitaxial layer;
forming a recessed gate electrode pattern of a transfer transistor configured to penetrate an inside of the substrate including the epitaxial layer;
forming a photodiode area over the epitaxial layer adjacent to a first side of the recessed gate electrode pattern;
forming a trap preventing layer over the photodiode area; and
forming a drain region within a surface of the substrate adjacent to a second side of the recessed gate electrode pattern, the second side being on an opposite side of the gate electrode pattern than the photodiode area.

2. The method of claim 1, wherein the photodiode area comprises a lightly doped n type diffusion area.

3. The method of claim 1, wherein the trap preventing layer comprises a heavily doped p type diffusion area.

4. The method of claim 1, wherein the drain region comprises a heavily doped n type diffusion area.

5. The method of claim 1, wherein the semiconductor substrate comprises a heavily doped p type (p++) substrate, and wherein the epitaxial layer comprises a lightly doped p type (p−) epitaxial layer.

6. The method of claim 1, wherein forming the recessed gate electrode pattern comprises:
forming a nitride layer over the substrate having a prescribed lower structure provided underneath and patterning the nitride layer; and
forming a trench on the substrate by performing dry etch using the patterned nitride layer as an etch mask to form a gate of the transfer transistor.

7. The method of claim 6, further comprising:
forming a gate oxide layer over the surface of the substrate including the trench; and
forming the recessed gate electrode pattern over the trench by forming and patterning polysilicon over the gate oxide layer.

8. The method of claim 6, wherein the trench is etched to have a slope of approximately 30˜90 degrees according to a design rule.

9. The method of claim 6, wherein the trench is formed to have a depth approximately 0.5˜2 times greater than that of the trap preventing layer.

10. A device, comprising:
a photodiode area formed in a semiconductor substrate;
a lower structure including a trap preventing layer over the photodiode area and a drain region; and
an electrode pattern of a recessed gate structure provided within the semiconductor substrate provided with the lower structure.

11. The device of claim 10, wherein the recessed gate structure comprises a gate electrode having at least a portion formed below a plane of an upper surface of the trap preventing layer.

12. The device of claim 11, wherein a portion of the gate electrode is formed over the upper surface of the trap preventing layer.

13. The device of claim 12, wherein the portion of the gate electrode formed over the upper surface of the trap preventing layer comprises outer edges of the gate electrode.

14. The device of claim 10, wherein the electrode pattern of the recessed gate structure is configured to have a slope of 30˜90 degrees and a depth 0.5˜2 times greater than that of the trap preventing layer.

15. A device, comprising:
a semiconductor substrate having an epitaxial formed thereon;
a gate electrode formed over the semiconductor substrate, wherein at least a portion of the gate electrode is recessed below a plane of a top surface of the epitaxial layer.

16. The device of claim 15, wherein a portion of the gate electrode at sides of the gate electrode are not recessed below the plane of the top surface of the epitaxial layer.

17. The device of claim 16, further composing a photodiode region formed on a first side of the gate electrode.

18. The device of claim 17, further comprising a trap preventing later over the photodiode region and a drain region on a second side of the gate electrode opposite of the photodiode region.

19. The device of claim 18, further comprising a trench etched into the epitaxial layer to form the recess for the gate electrode, and wherein the trench is etched to have a slope of approximately 30˜90 degrees according to a design rule.

20. The device of claim 19, wherein the trench is formed to have a depth approximately 0.5˜2 times greater than that of the trap preventing layer.
